(19) United States
(12) Patent Application Publication
(10) Pub. No.: US 2008/0251557 A1
(43) Pub. Date: Oct. 16, 2008

(54) Scribing unit and apparatus for scribing panel with the scribing unit, and scribing method and method for manufacutring substrate

(76) Inventor: Sang-Kil Kim, Chungcheongnam-do (KR)

Correspondence Address: JENKINS, WILSON, TAYLOR & HUNT, P. A., Suite 1200 UNIVERSITY TOWER, 3100 TOWER BLVD.,, DURHAM, NC, 27707, US

(21) Appl. No.: 12/077,064

(22) Filed: Mar. 14, 2008

(30) Foreign Application Priority Data
Apr. 12, 2007 (KR) 2007-36820

(51) Int. Cl. B28D 5/00; H01L 21/00

(52) U.S. Cl. 225/2; 225/96.5

(57) ABSTRACT

A scribing unit is provided to perform a scribing process in which unit substrate are separated from a panel where the unit substrates are formed. The scribing unit includes a megasonic vibrator, which applies a megasonic vibration to a wheel to make fracture surfaces of the unit substrates smooth. Therefore, it is possible to omit a process of grinding the edges of the fracture surface of the unit substrates before cleaning the separated unit substrates.

### CROSS-REFERENCE TO RELATED APPLICATIONS

This U. S non-provisional patent application claims priority under 35 U.S.C. §119 of Korean Patent Application 2007-35820 filed on Apr. 12, 2007, the entirety of which is hereby incorporated by reference.

### BACKGROUND

The present invention relates to apparatus and method used in manufacturing a panel. More specifically, the present invention is directed to a scribing unit for scribing a panel where a plurality of unit substrates are formed, a scribing apparatus with the scribing unit, and a scribing method and a method for manufacturing a substrate using the scribing method.

Lately, data processing apparatuses are rapidly being advanced with multiple functions and higher data processing speed. Each of these data processing apparatuses includes a display provided to display operated information. While cathode ray tubes (CRTs) are conventionally used as displays, flat panel displays such as thin film transistor liquid crystal displays (TFT-LCDs) or organic light emitting diode displays (OLEDs) are increasingly being used in recently years.

Generally, a plurality of unit substrates for use in a monitor or a television (TV) set are provided at a large-sized panel. Accordingly, there is a requirement for a process of separating the unit substrates from the large-sized panel.

A process of separating a large-sized panel into unit substrates includes a scribing process in which a vertical crack is formed at a panel by using a diamond wheel and a braking process in which a force is applied to a crack-formed portion by using a break bar to separate a panel into a plurality of unit substrates.

However, if a scribing process is carried out using a typical apparatus, the edges of fracture surfaces of unit substrates become rough. Accordingly, a grinding process of grinding the edges of the fracture surfaces of the unit substrates are required to make the fracture surface smooth. The grinding process causes increase of time required.

### SUMMARY OF THE INVENTION

Exemplary embodiments of the present invention are directed to a scribing unit used to cut a workpiece. In an exemplary embodiment, the scribing unit may include: a scriber contacting a workpiece to form a crack in a surface of the workpiece; a supporter configured to support the scriber; and a vibrator configured to provide a vibration to the scriber.

Exemplary embodiments of the present invention are directed to a panel scribing apparatus for performing a scribing process before separating unit substrates from a panel where the unit substrates are formed. In an exemplary embodiment, the apparatus may include: a support member on which a panel is placed; a scribing unit configured to scribe the panel placed on the support member; a first moving unit configured to straightly move the scribing unit or the support member in a first direction; and a second moving unit configured to straightly move the scribing unit in a second direction that is perpendicular to the first direction, wherein the scribing unit comprises: a scriber contacting a workpiece to form a crack in a surface of the workpiece; a supporter configured to support the scriber; and a vibrator configured to provide a vibration to the scriber.

Exemplary embodiments of the present invention are directed to a method for scribing a workpiece. In an exemplary embodiment, the method may include: contacting a scriber with a workpiece; and making a relative movement between the workpiece and the scriber, wherein a vibration is applied to the scriber during a scribing process.

Exemplary embodiments of the present invention are directed to a method for manufacturing a substrate. In an exemplary embodiment, the method may include: performing a scribing process in which a panel, where unit substrates are formed, is scribed by means of a scriber; performing a breaking process in which the unit substrates are separated from the scribed panel; and performing a cleaning process in which the unit substrates are cleaned, wherein the scribing process is performed by applying a vibration to the scriber when the panel is scribed; and wherein the cleaning process is performed between the breaking process and the cleaning process without performing a grinding process in which fracture surfaces of the unit substrates are ground.

### BRIEF DESCRIPTION OF THE DRAWINGS

FIG. 1 is a perspective view illustrating an example of a panel for a flat panel display where a plurality of unit substrates are formed.

FIG. 2 illustrates an apparatus for separating a panel into a plurality of unit substrates according to the present invention.

FIG. 3 is a perspective view illustrating a scribing apparatus according to an embodiment of the present invention.

FIG. 4 is a perspective view of a scribing unit shown in FIG. 3.

FIGS. 5A and 5B are front views illustrating various examples of a wheel shown in FIG. 4, respectively.

FIG. 6 is a partial cross-sectional view of the scribing unit shown in FIG. 3.

FIGS. 7A and 7B comparatively illustrate a fracture surface of a unit substrate in the case where a scribe process is performed when a megasonic vibration is not applied and a fracture surface of a unit substrate in the case where a scribe process is performed when a megasonic vibration is applied.

FIG. 8 is a flowchart illustrating a method of manufacturing a flat panel display according to an embodiment of the present invention.

### DETAILED DESCRIPTION OF PREFERRED EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity.

While the embodiments of the present invention will specify a panel 10 for flat panel display as a cutting workpiece, the invention is not limited thereto and may be applied to other kinds of workpieces.

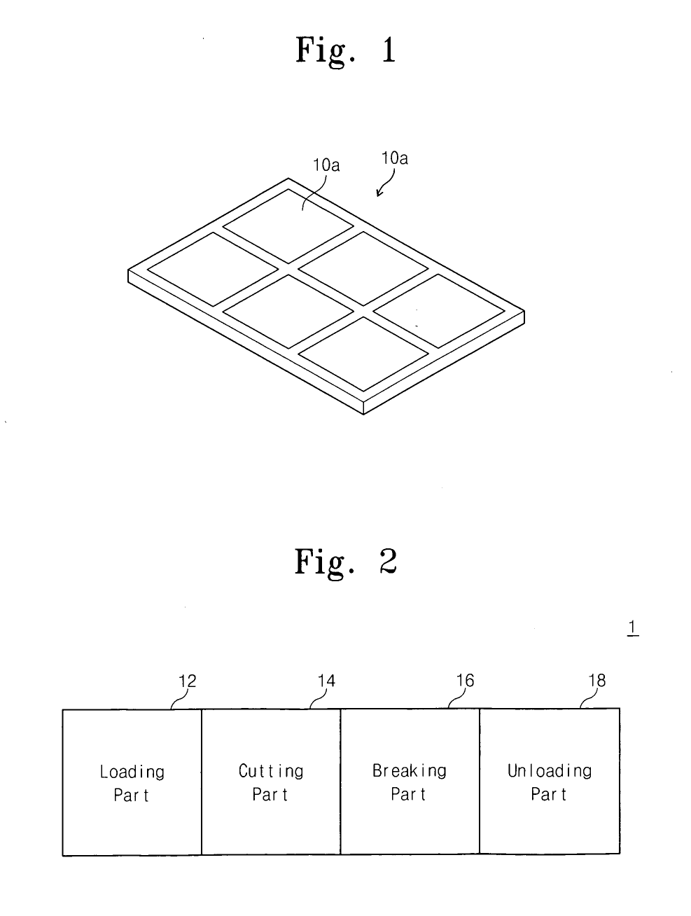

FIG. 1 illustrates an example of a panel 10, and FIG. 2 illustrates an apparatus 1 for separating the panel 10 illustrated in FIG. 1 into a plurality of unit substrates 10a. The panel 10 may be a panel for thin film transistor liquid crystal display (TFT-LCD) or a panel for organic light emitting diode display (OLED), which are a kind of a panel for flat panel display. As illustrated in FIG. 1, the panel 10 roughly exhibits the shape of rectangular plate, and a plurality of unit substrates 10a are formed at the panel 10. The apparatus 1 illustrated in FIG. 2 separates a panel 10 into a plurality of unit substrates 10a.

Referring to FIG. 2, the apparatus 1 includes a loading part 12, a scribing part 14, a breaking part 16, and an unloading part 18, which are arranged in a row in the order named. A panel 10 is put in the apparatus 1 through the loading part 12. After the panel 10 is separated into a plurality of unit substrates 10 while passing the scribing part 14 and the breaking part 16, the unit substrates 10 are put out to the exterior through the unloading part 18. The scribing part 14 forms a vertical crack at the panel 10 by using a scriber 420. The breaking part 16 applies a force a crack-formed portion of the panel 10 by using a break bar (not shown) to separate the separate units 10a from the panel 10.

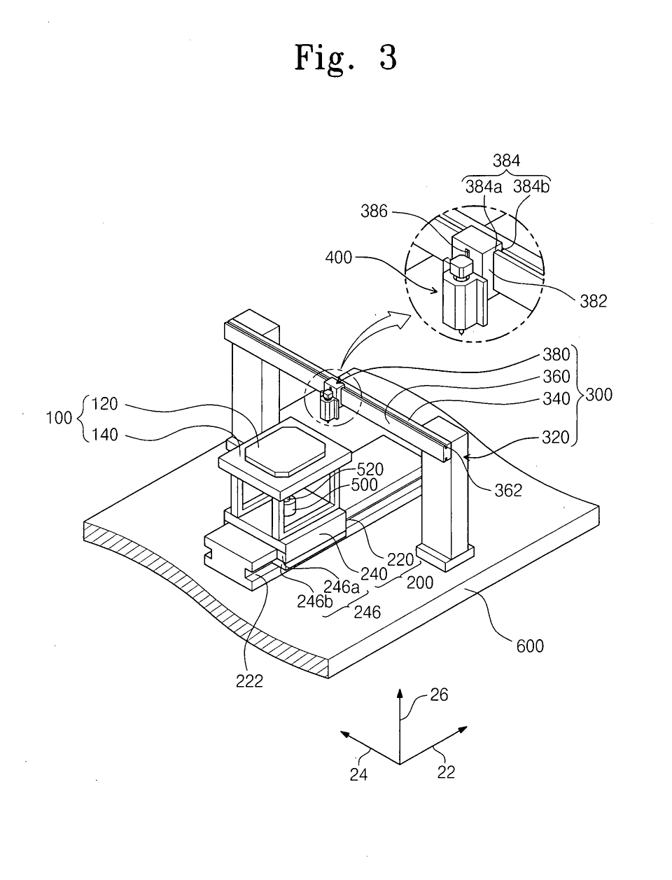

FIG. 3 is a perspective view of a scribing apparatus 14a provided at the scribing part 14 shown in FIG. 2. As illustrated in FIG. 3, the scribing apparatus 14a includes a table 120, a first moving unit 200, a second moving unit 300, a scribing unit 400, and a rotating unit 500. The panel 10 is placed on the table 100 during a scribing process.

The table 100 includes a top surface which is flat and roughly exhibits the shape of rectangle. The top surface of the table 100 has the same area as the panel 10 or a larger area than the panel 10. A plurality of holes connected to a vacuum line are formed at the top surface of the table 100 to fix the panel 10 to the table 100 by a vacuum press. A clamp (not shown) may be installed at the table 100 to additionally fix the panel 10 to the table 100.

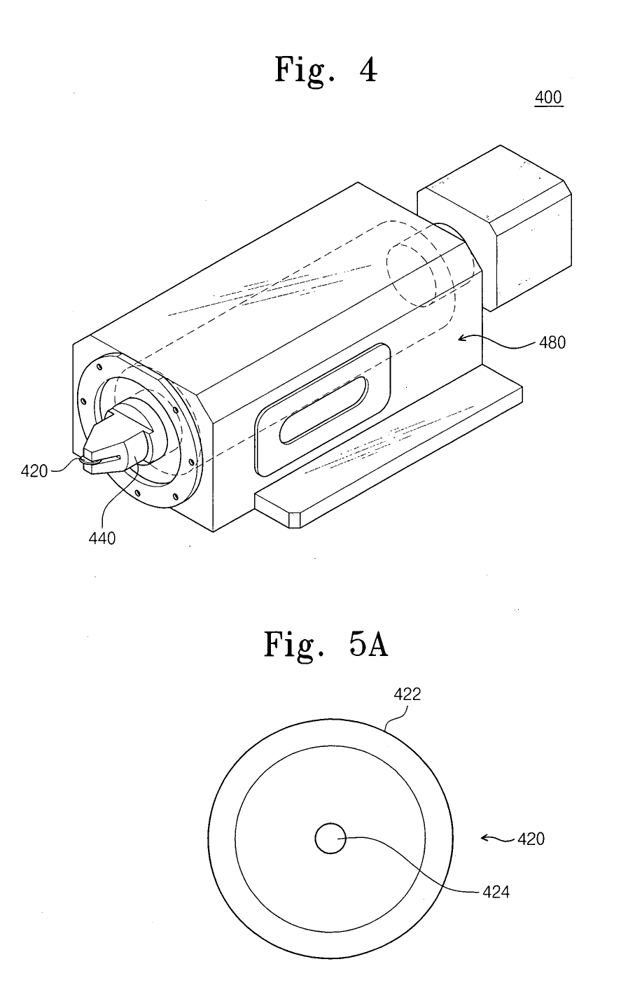

The scribing unit 400 draws lines at the panel 10 placed on the table 100 to form a crack. As illustrated in FIG. 4, the scribing unit 400 includes a scriber 420, a supporter 440, a vibrator 460, and a pressuring member 480. The scriber 420 is in direct contact with the panel 10 during a scribing process. A wheel made of diamond is used as the scriber 420. A though-hole 424 is formed at the center of the wheel 420. The edge of the wheel 420 is provided sharply. As illustrated in FIG. 5A, the edge of the wheel 420 may be provided circularly. Optionally, as illustrated in FIG. 5B, teeth 422a may be formed at the edge 422 of the wheel 420 along the circumference of the wheel 420. In the case that the wheel 420 illustrated in FIG. 5B is used, the efficiency of the scribing process is more excellent.

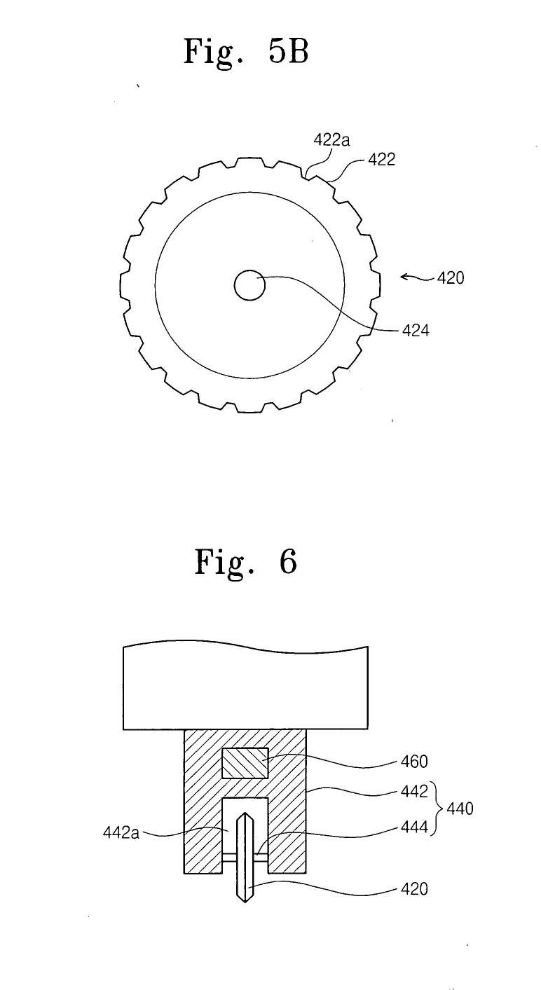

The wheel 420 is supported to the supporter 440. FIG. 6 is a cross-sectional view of the structure where the wheel 420 is installed at the supporter 440. As illustrated in FIG. 6, the supporter 440 includes a body 442 and a axle pin 444. A groove 442a is formed at the bottom surface of the body 442 to penetrate the body 442 in one direction. The axle pin 444 exhibits the shape of a long rod having a circular cross section. The axle pin 444 is disposed within a groove 442a in a direction that is perpendicular to a length direction of the a groove 442a. Both ends of the axle pin 444 are installed to be fixed to the body 442. The axle pin 444 penetrates the through-hole 424 formed at the wheel 420. When the wheel 420 is supported by means of the axle pin 444, a portion of the wheel 420 is disposed within the groove 442a and the other portion thereof protrudes downwardly from the supporter 440.

The pressuring member 480 pressurizes the wheel 420, allowing the wheel 420 to press the panel 10 with a constant force when the wheel 420 and the panel 10 are in contact with each other. In an exemplary embodiment, the pressuring member 480 is disposed over the supporter 440 and downwardly presses the supporter 440 using a pneumatic pressure to pressurize the wheel 420. The pressuring member 480 may be provided with a structure including a rod (not shown) elevated or lowered by the pneumatic pressure. Optionally, the pressuring member 480 may be provided with a structure where air directly pressurizes the body 442 of the wheel 420.

The vibrator 460 is mounted inside the body 442 and applies a vibration to the wheel 420 during a scribing process. A megasonic transducer may be used as the vibrator 460. The vibrator 460 may apply a vibration to the wheel 420 upwardly and downwardly. If the wheel 420 forms a crack at the panel 10, a fracture surface of the panel 10 generally becomes rough. It is therefore necessary that after unit substrates 10a are separated from the panel 10 by means of a break process, the edges of fracture surfaces of the unit substrates 10a are ground using a grind stone before a cleaning process. However, if a vibration is applied to the wheel 420 when the wheel 420 forms a crack at the panel 10, a fracture surface of the panel 10 becomes smooth. Thus, a process of grinding the unit substrates 10a may be omitted before cleaning the unit substrates 10a.

The first moving unit 200 allows the table 100 to move straight in a first direction 22. The first moving unit 200 includes a first guide 220, a first bracket 240, and a first driver (not shown). The first guide 220 is provided lengthwise in the first direction 22 and installed at the center on a base 600. The first guide 220 has the same width lengthwise. A top surface of the first guide 220 is provided to be flat. Grooves 222 are formed at both side surfaces of the first guide 220 lengthwise, respectively.

The table 100 is coupled with the first guide 220 by the first bracket 240. The first bracket 240 includes a base plate 242, a support plate 244, and a coupling plate 246. The base plate 242 is a rectangular flat plate, which is disposed on the first guide 220. The support plate 220 is fixed and coupled to the table 100 to support the table 100 from below. Two support plates 220 are provided and disposed to face each other. The coupling plate 246 includes a side plate 246a and an insert plate 246b. The side plate 246a is disposed to be perpendicular to the bottom surface of the base plate 242 and fixed and coupled thereto. The insert plate 246b extends from the bottom end of an inner side surface of the side plate 246a in a perpendicular direction to the side plate 246a to be inserted into the groove 222 formed at the side surface of the first guide 220. Two coupling insert plates 246b are provided to face each other.

The first driver provides a driving force to allow the table 100 to travel straight. Optionally, the first driver may be an assembly including a motor, a belt, and a pulley. Optionally, the first driver may be an assembly including a linear motor. The above assemblies are well known in the art and their detailed configurations will not be described.

The second moving unit 300 allows the scribing unit 400 to move straight in a second direction 24, which is perpendicular to the first direction 22. The second moving unit 300 includes vertical supports 320, a horizontal support 340, a second guide 360, and a second bracket 380, and a second driver (not shown). The vertical supports 320 are fixed and installed on a base 600 to be spaced apart from each other at regular intervals. The vertical supports 320 are disposed to allow the panel 10 to pass between the vertical supports 320 when the panel 10 moves in the first direction 22. The horizontal support 340 is fixed and installed at the top ends of the vertical supports 320. The second guide 360 is provided at one side surface of the horizontal support 340 in a length direction of the horizontal support 340. Grooves are provided at the top and bottom surface of the second guide 360 in a length direction of the second guide 360. The second guide 360 and the horizontal support 340 may be provided in one body.

The scribing unit 400 is coupled with the horizontal support 340 by the second bracket 380. The second bracket 380 includes a support plate 382 and a coupling plate 384. The support plate 382 is a rectangular flat plate, which is disposed on the second guide 360. The coupling plate 384 includes a side plate 384a and an insert plate 384b. The side plate 384a protrudes vertically to the support plate 382 from top and bottom sides of the support plate 382, and the insert plate 384b is inserted into a groove 362 formed at the second guide 360. The second driver provides a driving force to allow the scribing unit 400 to travel straight along the second guide 360. The second driver may be provided with a similar configuration to the first driver.

The scribing unit 400 is installed at the support plate 382 to be movable up and down. In an exemplary embodiment, a slit-type guide groove 386 is formed at the support plate 382 in a third direction 384 and the scribing unit 400 is coupled with a support shaft (not shown) inserted into the guide groove 386. The third direction 384 is perpendicular to the first direction 22 as well as the second direction 24. In FIG. 3, the third direction 384 is an up-and-down perpendicular direction. A third driver (not shown) provides a driving force to allow the scribing unit 400 to travel straight. A motor or a cylinder may be used as the third driver.

The rotating unit 500 rotates the panel 10 to provide a crack in a direction lying at right angles to the panel 10. In an exemplary embodiment, the table 100 includes a top plate 120 and a bottom plate 140. The bottom plate 140 is fixed to the first bracket 240, and the top plate 120 is coupled with the bottom plate 140 to be rotatable relative to the bottom plate 140 over a horizontal surface. A rotation shaft 500, which is coupled with the motor 500, is fixedly installed at the bottom surface of the top plate 120.

A method of scribing the panel 10 using the scribing apparatus 14a illustrated in FIG. 3 will now be described in detail. An aligned panel 10 is placed on a table 100. The table 100 travels straight in a first direction 22. When the table 100 reaches a first position set previously, the movement of the table 100 stops. Afterwards, a scribing unit 400 travels straight in a second direction 24. When the scribing unit 400 reaches a preset position, the movement of the scribing unit 400 stops. Thereafter, the scribing unit 400 travels downwardly and a wheel 420 comes in contact with the panel 10. The wheel 420 is pressurized by a pressuring member 480 to press the panel 10. While the wheel 420 presses the panel 10, a megasonic vibration is applied to the wheel 420. The table 100 travels straight to a second position in the first direction 22. While pressing the panel 10, the wheel 420 rotates on a axle pin 444. A crack is linearly formed at the panel 10. If a crack is formed from one end to the other end of the panel 10, the scribing unit 400 travels upwardly and the table 100 returns to the first position. The scribing unit 400 travels a preset distance straight in a second direction 24, and the scribing unit 400 travels downwardly. As the table 100 moves to the second position, a crack is formed at the panel 10. Such steps are repeated. Afterwards, the table 100 rotates at 90 degrees and the foregoing steps are repeated.

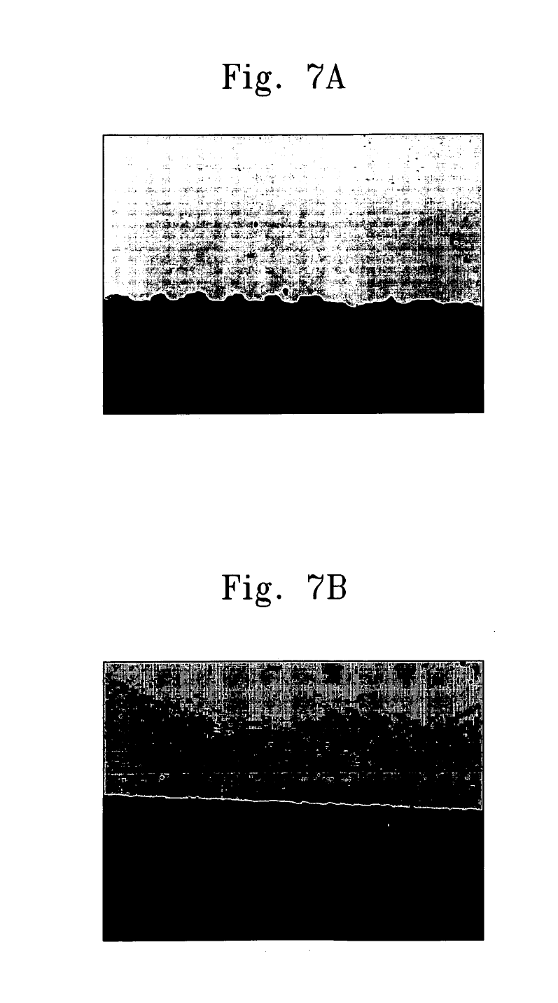

FIG. 7A is a photograph showing the state of a fracture surface when a scribing process is performed without providing a megasonic vibration to the wheel 420. FIG. 7B is a photograph showing the state of a fracture surface when a scribing process is performed by providing a megasonic vibration to the wheel 420. As illustrated in FIGS. 7A and 7B, the fracture surface is smoother in case a megasonic vibration is provided to the wheel 420.

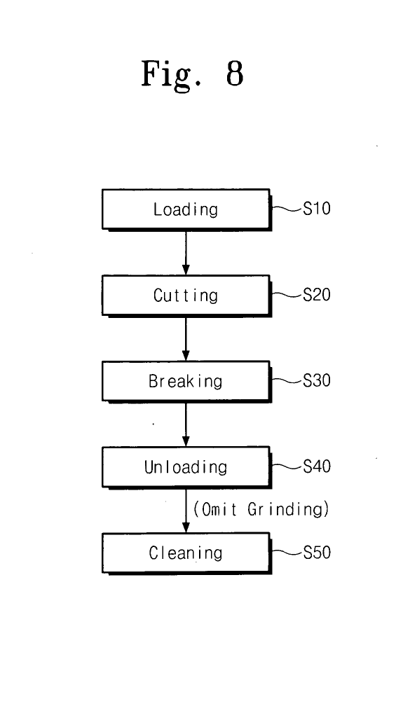

FIG. 8 illustrates a method of manufacturing a flat panel display using the scribing apparatus 14a shown in FIG. 3. Referring to FIG. 8, a panel 10 is loaded (S10). A scribing process and a breaking process are sequentially performed for the loaded panel 10 (S20 and S30). If the panel 10 is separated into a plurality of unit substrates 10a, the unit substrates 10a are unloaded (S40). Without a grinding process, a cleaning process is directly performed for the unit substrates 10a (S50). As a megasonic vibration is applied during the scribing process, a fracture surface becomes significantly smooth. Therefore, it is not necessary to perform the grinding process.

Various modified embodiments will now be described below in brief.

The above embodiment specifies that a first driving unit 200 allows a table 100 to travel straight in a first direction 22. However, the table 100 may be fixed and a scribing unit 400 may travel straight in the first direction 22 during a scribing process. In this case, a vertical supports 362 may travel straight in the first direction 22.

Further, the above embodiment specifies that one scribing unit 400 is coupled with a horizontal support shaft to scribe a panel 10 only while the panel 10 travels from a first position to a second position. However, two scribing units 400 may be installed at a horizontal support 364. In this case, a first scribing unit performs the scribing process while the panel 10 travels from a first position to a second position and a second scribing unit performs the scribing process while the panel 10 travels from the second position to the first position. The above method makes it possible to reduce the time required for performing a scribing process.

Further, the above embodiment specifies that the scribing apparatus 14a is configured to perform a scribing process for the top surface of the panel 10. In the case that there is a requirement to perform a scribing process for the rear surface of the panel 10, the scribing apparatus 14a may include a unit to invert the top and bottom surfaces of the panel 10. Optionally, two horizontal supports 364 may be installed at a vertical support 362; a top scribing unit may be installed at the overlying horizontal support 364 to perform a scribing process for the top surface of the panel 10; and a bottom scribing unit may be installed at the underlying horizontal support 364 to perform a scribing process for the bottom surface of the panel 10. This makes it possible to reduce the time required for performing a scribing process.

Further, the above embodiment specifies that a cleaning process is performed without a process of grinding fracture surfaces of the unit substrates 10a. However, in the case that there is a requirement for smoother fracture surfaces, a process may be performed to grind the fracture surfaces of the unit substrates 10 before the cleaning process is performed.

Further, the above embodiment specifies that a table 100 for supporting the entire bottom surface of the panel 10 is used as a support member for supporting the panel 10. However, the support member may have various configurations such as a configuration to support only both edges of the panel 10.

According to the present invention, relatively smooth fracture surfaces are achieved when a panel is separated into a plurality of unit substrates. In addition, after a panel is separated into a plurality of unit substrates, a cleaning process is directly performed without a grinding process to reduce the time required for the overall process time and decrease the area of equipment because a unit for performing the grinding process is not required.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the invention.

What is claimed is:

1. A scribing unit used to cut a workpiece, comprising:
a scriber contacting a workpiece to form a crack in a surface of the workpiece;
a supporter configured to support the scriber; and
a vibrator configured to provide a vibration to the scriber.

2. The scribing unit of claim 1, wherein the scriber comprises a rotatable wheel; and
wherein the supporter further comprises a body; and an axle pin coupled with the body and inserted into a through-hole formed at the wheel to rotatably support the wheel.

3. The scribing unit of claim 2, wherein a groove is formed in a bottom surface of the body and a portion of the wheel is inserted in the groove; and
wherein the axle pin is fixedly installed at the body within the groove.

4. The scribing unit of claim 2, wherein the vibrator is provided inside the body.

5. The scribing unit of claim 1, wherein the vibrator is a megasonic vibrator.

6. The scribing unit of claim 2, wherein the wheel includes the edge where teeth are formed.

7. The scribing unit of claim 1, wherein the scribing unit further comprises a pressuring member disposed over the supporter and configured to pressurize the supporter using a pneumatic pressure.

8. A panel scribing apparatus for performing a scribing process before separating unit substrates from a panel where the unit substrates are formed, the apparatus comprising:
a support member on which a panel is placed;
a scribing unit configured to scribe the panel placed on the support member;
a first moving unit configured to straightly move the scribing unit or the support member in a first direction; and
a second moving unit configured to straightly move the scribing unit in a second direction that is perpendicular to the first direction,
wherein the scribing unit comprises:
a scriber contacting a workpiece to form a crack in a surface of the workpiece;
a supporter configured to support the scriber; and
a vibrator configured to provide a vibration to the scriber.

9. The panel scribing apparatus of claim 8, wherein the scriber comprises a rotatable wheel; and
wherein the supporter comprises a body that a groove is formed in a bottom surface thereof and an axle pin that is installed to be fixed to the body within the groove,
wherein a portion of the wheel is inserted in the groove and the axle pin is inserted into an opening formed at the wheel to rotatably support the wheel.

10. The panel scribing apparatus of claim 9, wherein the vibrator is a megasonic vibrator disposed inside the body.

11. The panel scribing apparatus of claim 9, wherein the scribing unit further comprises a pressuring member disposed over the supporter and configured to pressurize the supporter using a pneumatic pressure.

12. The panel scribing apparatus of claim 9, wherein the support member comprises a table on which a panel is placed; and
wherein the scribing unit further comprises a rotating unit configured to rotate the table.

13. A method for scribing a workpiece, comprising:
contacting a scriber with a workpiece; and
making a relative movement between the workpiece and the scriber,
wherein a vibration is applied to the scriber during a scribing process.

14. The method of claim 13, wherein the vibration is a megasonic vibration.

15. The method of claim 13, wherein the scriber is a wheel that is rotatable along the surface of the workpiece during a relative movement between the workpiece and the scriber.

16. The method of claim 13, wherein the scriber is pressurized by a gas when the scriber is in contact with the workpiece.

17. A method for manufacturing a substrate, comprising:
scribing a panel where unit substrates are formed
breaking the scribed panel so that the unit substrates are separated from the scribed panel; and
cleaning the unit substrates;
wherein the scribing a panel is performed by applying a vibration to a scriber; and
wherein the cleaning the unit substrates is performed between the breaking process and the cleaning process without grinding fracture surfaces of the unit substrates.

18. The method of claim 17, wherein the vibration is a megasonic vibration.

19. The method of claim 17, wherein the scriber is pressurized by a gas when the scriber is in contact with the workpiece.

20. The method of claim 17, wherein the panel is a panel for a flat panel display.
